(19) United States
(12) Patent Application Publication
(10) Pub. No.: US 2023/0134613 A1
(43) Pub. Date: May 4, 2023

(54) DETECTION DEVICE

(71) Applicant: Japan Display Inc., Tokyo (JP)

(72) Inventor: Takanori TSUNASHIMA, Tokyo (JP)

(21) Appl. No.: 17/979,522

(22) Filed: Nov. 2, 2022

(30) Foreign Application Priority Data
Nov. 4, 2021 (JP) 2021-180300

(51) Int. Cl. H01L 27/146; G06V 40/13

(52) U.S. Cl. CPC H01L 27/14652; G06V 40/1318

(57) ABSTRACT

According to an aspect, a detection device includes: a substrate; a plurality of first electrodes arranged on the substrate; an insulating film provided between the first electrodes adjacent to each other; a plurality of photodiodes provided so as to correspond to the first electrodes; and a second electrode provided across the photodiodes. The photodiodes each comprise a first carrier transport layer, an active layer, and a second carrier transport layer stacked on the substrate. The first carrier transport layer, the active layer, and the second carrier transport layer are provided so as to cover the first electrodes and the insulating film between the adjacent first electrodes.

### CROSS-REFERENCE TO RELATED APPLICATION

This application claims the benefit of priority from Japanese Patent Application No. 2021-180300 filed on Nov. 4, 2021, the entire contents of which are incorporated herein by reference.

### BACKGROUND

### 1. Technical Field

What is disclosed herein relates to a detection device.

### 2. Description of the Related Art

Optical sensors capable of detecting fingerprint patterns and vascular patterns are known (for example, Japanese Patent Application Laid-open Publication No. 2009-032005). Among such optical sensors, sensors are known each including a plurality of photodiodes each including an organic semiconductor material used as an active layer.

When an organic semiconductor layer is provided across a plurality of detection electrodes, a leakage current may be generated between the adjacent detection electrodes. This possibly makes it difficult to achieve a higher resolution of detection in the optical sensors each having a plurality of photodiodes.

For the foregoing reasons, there is a need for a detection device capable of reducing a leakage current between detection electrodes.

### SUMMARY

According to an aspect, a detection device includes: a substrate; a plurality of first electrodes arranged on the substrate; an insulating film provided between the first electrodes adjacent to each other; a plurality of photodiodes provided so as to correspond to the first electrodes; and a second electrode provided across the photodiodes. The photodiodes each comprise a first carrier transport layer, an active layer, and a second carrier transport layer stacked on the substrate. The first carrier transport layer, the active layer, and the second carrier transport layer are provided so as to cover the first electrodes and the insulating film between the adjacent first electrodes.

### BRIEF DESCRIPTION OF THE DRAWINGS

FIG. 1 is a plan view illustrating a detection device according to a first embodiment;

FIG. 2 is a block diagram illustrating a configuration example of the detection device according to the first embodiment;

FIG. 3 is a circuit diagram illustrating the detection device;

FIG. 4 is a circuit diagram illustrating a plurality of partial detection areas;

FIG. 5 is a timing waveform diagram illustrating an operation example of the detection device;

FIG. 6 is a timing waveform diagram illustrating an operation example during a reading period in FIG. 5;

FIG. 7 is a magnified schematic configuration diagram of a sensor;

FIG. 8 is a VIII-VIII′ sectional view of FIG. 7;

FIG. 9 is a magnified schematic sectional view illustrating a magnified view of a multilayered structure of first electrodes, an insulating film, photodiodes, and a second electrode in FIG. 8;

FIG. 10 is a magnified schematic configuration diagram of the sensor of a detection device according to a second embodiment;

FIG. 11 is a magnified schematic sectional view illustrating a magnified view of a multilayered structure of the first electrodes, shield wiring, the insulating film, the photodiodes, and the second electrode of the detection device according to the second embodiment; and

FIG. 12 is a magnified schematic sectional view illustrating a magnified view of a multilayered structure of the first electrodes, the shield wiring, the insulating film, the photodiodes, and the second electrode of a detection device according to a modification of the second embodiment.

### DETAILED DESCRIPTION

The following describes modes (embodiments) for carrying out the present invention in detail with reference to the drawings. What is disclosed herein is not limited to the description of the embodiments given below. Components described below include those easily conceivable by those skilled in the art or those substantially identical thereto. In addition, the components described below can be combined as appropriate. The present disclosure is merely an example and naturally encompasses appropriate modifications easily conceivable by those skilled in the art while maintaining the gist of the present disclosure. To further clarify the description, the drawings may schematically illustrate, for example, widths, thicknesses, and shapes of various parts as compared with actual aspects thereof. However, they are merely examples, and interpretation of the present disclosure is not limited thereto. The same component as that described with reference to an already mentioned drawing is denoted by the same reference numeral through the present disclosure and the drawings, and detailed description thereof may not be repeated where appropriate.

In the present specification and claims, in expressing an aspect of disposing another structure on or above a certain structure, a case of simply expressing “on” includes both a case of disposing the other structure immediately on the certain structure so as to contact the certain structure and a case of disposing the other structure above the certain structure with still another structure interposed therebetween, unless otherwise specified.

### First Embodiment

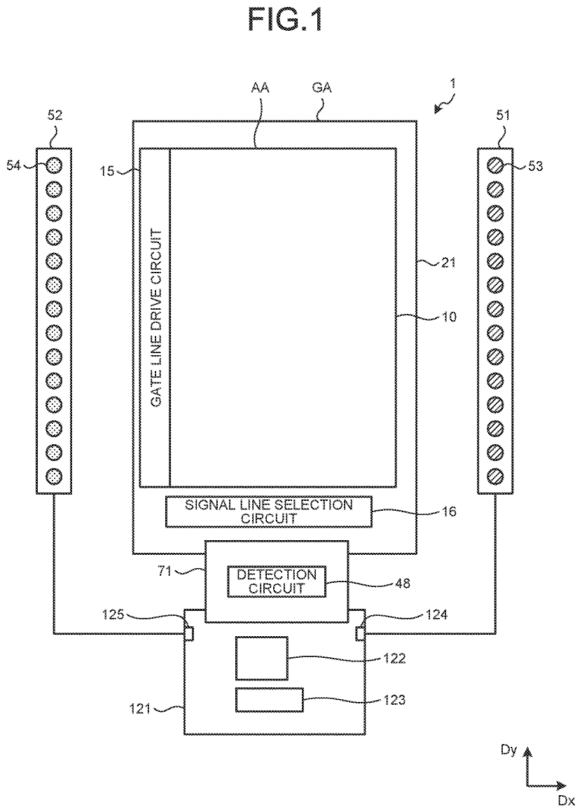

FIG. 1 is a plan view illustrating a detection device according to a first embodiment. As illustrated in FIG. 1, a detection device 1 includes a sensor base member 21 (substrate), a sensor 10, a gate line drive circuit 15, a signal line selection circuit 16, a detection circuit 48, a control circuit 122, a power supply circuit 123, a first light source base member 51, a second light source base member 52, and light sources 53 and 54. The first light source base member 51 is provided with the light sources 53. The second light source base member 52 is provided with the light sources 54.

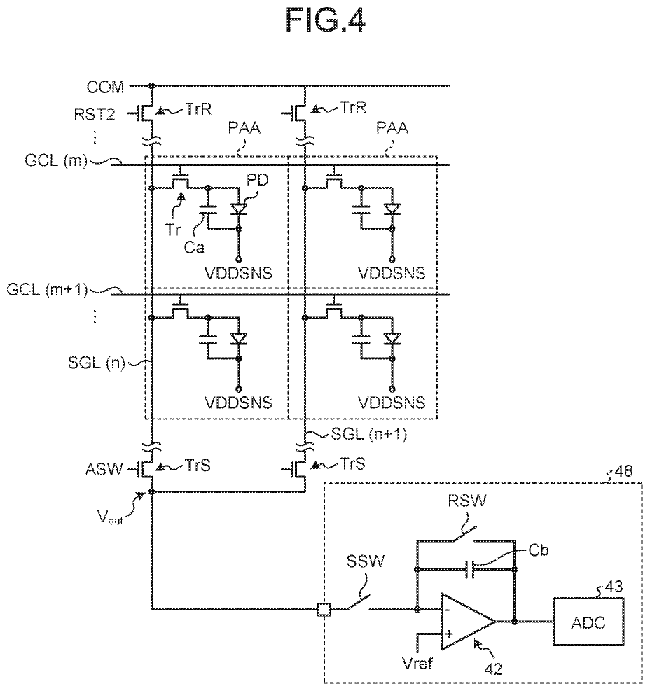

The sensor base member 21 is electrically coupled to a control substrate 121 through a flexible printed circuit board 71. The flexible printed circuit board 71 is provided with the detection circuit 48. The control substrate 121 is provided with the control circuit 122 and the power supply circuit 123. The control circuit 122 is, for example, a field-programmable gate array (FPGA). The control circuit 122 supplies control signals to the sensor 10, the gate line drive circuit 15, and the signal line selection circuit 16 to control a detection operation of the sensor 10. The control circuit 122 supplies control signals to the light sources 53 and 54 to control lighting and non-lighting of the light sources 53 and 54. The power supply circuit 123 supplies voltage signals including, for example, a sensor power supply signal (sensor power supply voltage) VDDSNS (refer to FIG. 4) to the sensor 10, the gate line drive circuit 15, and the signal line selection circuit 16. The power supply circuit 123 supplies a power supply voltage to the light sources 53 and 54.

The sensor base member 21 has a detection area AA and a peripheral area GA. The detection area AA is an area provided with a plurality of photodiodes PD (refer to FIG. 4) included in the sensor 10. The peripheral area GA is an area between the outer perimeter of the detection area AA and ends of the sensor base member 21 and is an area not provided with the photodiodes PD.

The gate line drive circuit 15 and the signal line selection circuit 16 are provided in the peripheral area GA. Specifically, the gate line drive circuit 15 is provided in an area extending along a second direction Dy in the peripheral area GA. The signal line selection circuit 16 is provided in an area extending along a first direction Dx in the peripheral area GA, and is provided between the sensor 10 and the detection circuit 48.

In the following descriptions, the first direction Dx is one direction in a plane parallel to the sensor base member 21. The second direction Dy is one direction in the plane parallel to the sensor base member 21 and is a direction orthogonal to the first direction Dx. The second direction Dy may non-orthogonally intersect the first direction Dx. The term “plan view” refers to a positional relation when viewed from a direction orthogonal to the sensor base member 21.

The light sources 53 are provided on the first light source base member 51, and are arranged along the second direction Dy. The light sources 54 are provided on the second light source base member 52, and are arranged along the second direction Dy. The first light source base member 51 and the second light source base member 52 are electrically coupled, through respective terminals 124 and 125 provided on the control substrate 121, to the control circuit 122 and the power supply circuit 123.

For example, inorganic light-emitting diodes (LEDs) or organic electroluminescent (EL) diodes (organic light-emitting diodes (OLEDs)) are used as the light sources 53 and 54. The light sources 53 and 54 emit light having wavelengths different from each other.

First light emitted from the light sources 53 is mainly reflected on a surface of an object to be detected such as a finger, and is incident on the sensor 10. As a result, the sensor 10 can detect a fingerprint by detecting a shape of asperities on the surface of the finger or the like. Second light emitted from the light sources 54 is mainly reflected in the finger or the like, or transmitted through the finger or the like, and is incident on the sensor 10. As a result, the sensor 10 can detect information on a living body in the finger or the like. Examples of the information on the living body include a pulse wave, pulsation, and a vascular image of the finger or a palm. That is, the detection device 1 may be configured as a fingerprint detection device to detect a fingerprint or a vein detection device to detect a vascular pattern of, for example, veins.

The first light may have a wavelength of from 500 nm to 600 nm, for example, a wavelength of approximately 550 nm, and the second light may have a wavelength of from 780 nm to 950 nm, for example, a wavelength of approximately 850 nm. In this case, the first light is blue or green visible light, and the second light is infrared light. The sensor 10 can detect a fingerprint based on the first light emitted from the light sources 53. The second light emitted from the light sources 54 is reflected in the object to be detected, such as the finger, or transmitted through or absorbed by the finger or the like, and is incident on the sensor 10. As a result, the sensor 10 can detect the pulse wave or the vascular image (vascular pattern) as the information on the living body in the finger or the like.

Alternatively, the first light may have a wavelength of from 600 nm to 700 nm, for example, approximately 660 nm, and the second light may have a wavelength of from 780 nm to 900 nm, for example, approximately 850 nm. In this case, the sensor 10 can detect a blood oxygen saturation level in addition to the pulse wave, the pulsation, and the vascular image as the information on the living body based on the first light emitted from the light sources 53 and the second light emitted from the light sources 54. Thus, since the detection device 1 includes the light sources 53 and 54, the detection device 1 can detect the various information on the living body by performing the detection based on the first light and the detection based on the second light.

The arrangement of the light sources 53 and 54 illustrated in FIG. 1 is merely an example, and may be changed as appropriate. The detection device 1 is provided with a plurality of types of the light sources 53 and 54 as light sources. However, the light sources are not limited thereto, and may be of one type. For example, the light sources 53 and 54 may be disposed on each of the first and the second light source base members 51 and 52. The light sources 53 and 54 may be provided on one light source base member, or three or more light source base members. Alternatively, only at least one light source needs to be disposed.

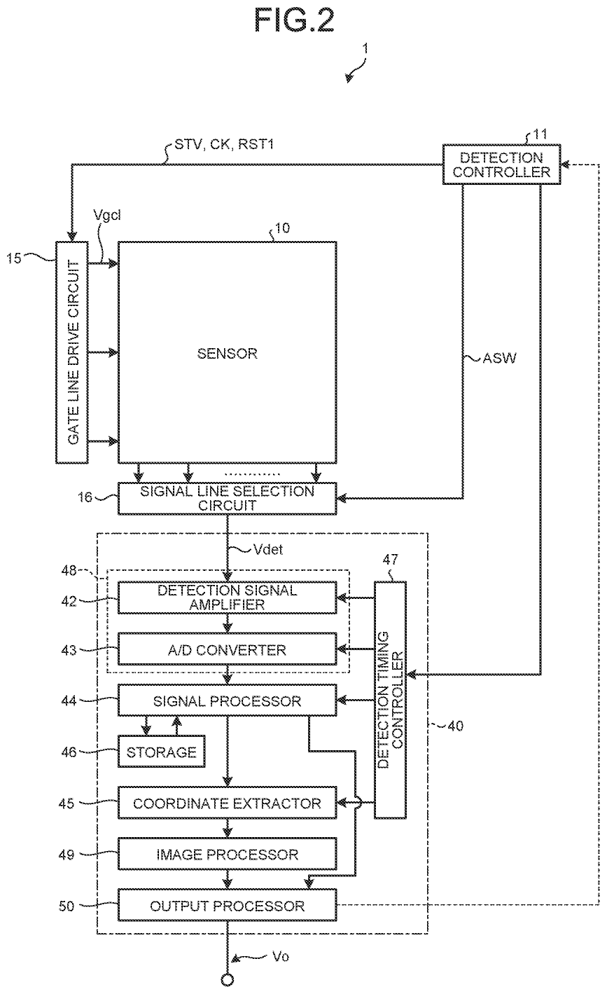

FIG. 2 is a block diagram illustrating a configuration example of the detection device according to the first embodiment. As illustrated in FIG. 2, the detection device 1 further includes a detection controller (detection control circuit) 11 and a detector (detection signal processing circuit) 40. The control circuit 122 includes one, some, or all of the functions of the detection controller 11. The control circuit 122 also includes one, some, or all of the functions of the detector 40 except those of the detection circuit 48.

The sensor 10 includes the photodiodes PD. Each of the photodiodes PD included in the sensor 10 outputs an electrical signal corresponding to light irradiating the photodiode PD as a detection signal Vdet to the signal line selection circuit 16. The sensor 10 performs the detection in response to a gate drive signal Vgcl supplied from the gate line drive circuit 15.

The detection controller 11 is a circuit that supplies respective control signals to the gate line drive circuit 15, the signal line selection circuit 16, and the detector 40 to control operations thereof. The detection controller 11 supplies various control signals such as a start signal STV, a clock signal CK, and a reset signal RST1 to the gate line drive circuit 15. The detection controller 11 also supplies various control signals such as a selection signal ASW to the signal line selection circuit 16. The detection controller 11 supplies various control signals to the light sources 53 and 54 to control the lighting and non-lighting of the respective light sources 53 and 54.

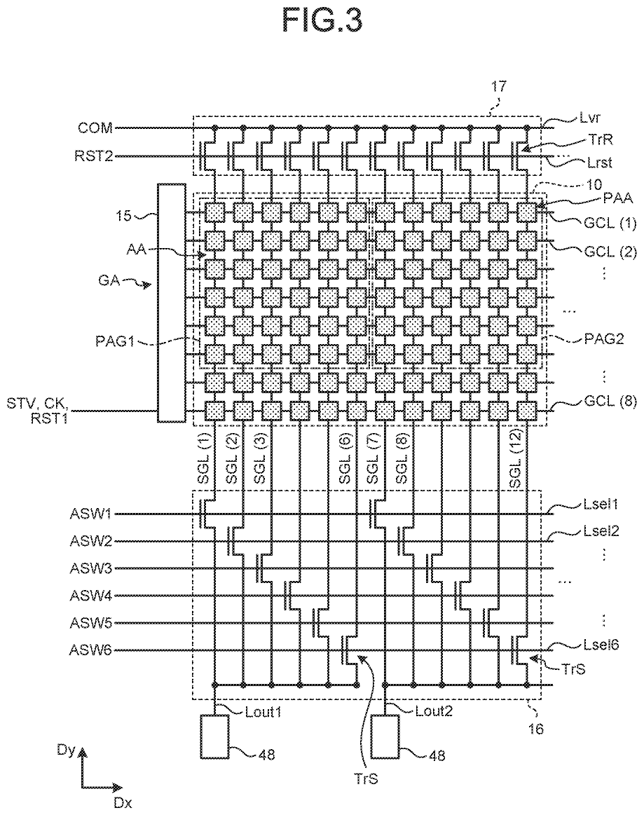

The gate line drive circuit 15 is a circuit that drives a plurality of gate lines GCL (refer to FIG. 3) based on the various control signals. The gate line drive circuit 15 sequentially or simultaneously selects the gate lines GCL, and supplies the gate drive signals Vgcl to the selected gate lines GCL. By this operation, the gate line drive circuit 15 selects the photodiodes PD coupled to the gate lines GCL.

The signal line selection circuit 16 is a switch circuit that sequentially or simultaneously selects a plurality of signal lines SGL (refer to FIG. 3). The signal line selection circuit 16 is, for example, a multiplexer. The signal line selection circuit 16 couples the selected signal lines SGL to the detection circuit 48 based on the selection signal ASW supplied from the detection controller 11. By this operation, the signal line selection circuit 16 outputs the detection signals Vdet of the photodiodes PD to the detector 40.

The detector 40 includes the detection circuit 48, a signal processor (signal processing circuit) 44, a coordinate extractor (coordinate extraction circuit) 45, a storage (storage circuit) 46, a detection timing controller (detection timing control circuit) 47, an image processor (image processing circuit) 49, and an output processor (output processing circuit) 50. Based on a control signal supplied from the detection controller 11, the detection timing controller 47 controls the detection circuit 48, the signal processor 44, the coordinate extractor 45, and the image processor 49 so as to operate in synchronization with one another.

The detection circuit 48 is, for example, an analog front-end (AFE) circuit. The detection circuit 48 is a signal processing circuit having functions of at least a detection signal amplifier 42 and an analog-to-digital (A/D) converter 43. The detection signal amplifier 42 amplifies the detection signals Vdet. The A/D converter 43 converts analog signals output from the detection signal amplifier 42 into digital signals.

The signal processor 44 is a logic circuit that detects a predetermined physical quantity received by the sensor 10 based on an output signal of the detection circuit 48. When the finger is in contact with or in proximity to a detection surface, the signal processor 44 can detect the asperities on the surface of the finger or the palm based on the signal from the detection circuit 48. The signal processor 44 can also detect the information on the living body based on the signal from the detection circuit 48. Examples of the information on the living body include the vascular image, the pulse wave, the pulsation, and the blood oxygen level of the finger or the palm.

The signal processor 44 may also perform processing of acquiring the detection signals Vdet (information on the living body) simultaneously detected by the photodiodes PD, and averaging the detection signals Vdet. In this case, the detector 40 can perform stable detection by reducing measurement errors caused by noise or relative positional misalignment between the object to be detected, such as the finger, and the sensor 10.

The storage 46 temporarily stores therein a signal calculated by the signal processor 44. The storage 46 may be, for example, a random-access memory (RAM) or a register circuit.

The coordinate extractor 45 is a logic circuit that obtains detected coordinates of the asperities on the surface of the finger or the like when the contact or the proximity of the finger is detected by the signal processor 44. The coordinate extractor 45 is also a logic circuit that obtains detected coordinates of blood vessels of the finger or the palm. The image processor 49 combines the detection signals Vdet output from the respective photodiodes PD of the sensor 10 to generate two-dimensional information indicating the shape of the asperities on the surface of the finger or the like and two-dimensional information indicating the shape of the blood vessels of the finger or the palm. The coordinate extractor 45 may output the detection signals Vdet as sensor output voltages Vo instead of calculating the detected coordinates. A case can be considered where the detector 40 does not include the coordinate extractor 45 and the image processor 49.

The output processor 50 serves as a processor that performs processing based on the outputs from the photodiodes PD. The output processor 50 may include, for example, the detected coordinates obtained by the coordinate extractor 45 and the two-dimensional information generated by the image processor 49 in the sensor output voltages Vo. The function of the output processor 50 may be integrated into another component (such as the image processor 49).

The following describes a circuit configuration example of the detection device 1. FIG. 3 is a circuit diagram illustrating the detection device. As illustrated in FIG. 3, the sensor 10 has a plurality of partial detection areas PAA arranged in a matrix having a row-column configuration. Each of the partial detection areas PAA is provided with the photodiode PD.

The gate lines GCL extend in the first direction Dx, and are coupled to the partial detection areas PAA arranged in the first direction Dx. A plurality of gate lines GCL(1), GCL(2), . . . , GCL(8) are arranged in the second direction Dy, and are each coupled to the gate line drive circuit 15. In the following description, the gate lines GCL(1), GCL(2), . . . , GCL(8) will each be simply referred to as the gate line GCL when they need not be distinguished from one another. For ease of understanding of the description, FIG. 3 illustrates eight gate lines GCL. However, this is merely an example, and M gate lines GCL (where M is eight or larger, and is, for example, 256) may be arranged.

The signal lines SGL extend in the second direction Dy, and are coupled to the photodiodes PD of the partial detection areas PAA arranged in the second direction Dy. A plurality of signal lines SGL(1), SGL(2), . . . , SGL(12) are arranged in the first direction Dx, and are each coupled to the signal line selection circuit 16 and a reset circuit 17. In the following description, the signal lines SGL(1), SGL(2), . . . , SGL(12) will each be simply referred to as the signal line SGL when they need not be distinguished from one another.

For ease of understanding of the description, 12 signal lines SGL are illustrated. However, this is merely an example, and N signal lines SGL (where N is 12 or larger, and is, for example, 252) may be arranged. The resolution of the sensor is, for example, 508 dots per inch (dpi), and the number of cells is 252×256. In FIG. 3, the sensor 10 is provided between the signal line selection circuit 16 and the reset circuit 17. The present disclosure is not limited thereto. The signal line selection circuit 16 and the reset circuit 17 may be coupled to ends of the signal lines SGL in the same direction.

The gate line drive circuit 15 receives the various control signals such as the start signal STV, the clock signal CK, and the reset signal RST1 from the control circuit 122 (refer to FIG. 1). The gate line drive circuit 15 sequentially selects the gate lines GCL(1), GCL(2), . . . , GCL(8) in a time-division manner based on the various control signals. The gate line drive circuit 15 supplies the gate drive signal Vgcl to the selected one of the gate lines GCL. This operation supplies the gate drive signal Vgcl to a plurality of first switching elements Tr coupled to the gate line GCL, and corresponding ones of the partial detection areas PAA arranged in the first direction Dx are selected as detection targets.

The signal line selection circuit 16 includes a plurality of selection signal lines Lsel, a plurality of output signal lines Lout, and third switching elements TrS. The third switching elements TrS are provided corresponding to the signal lines SGL. Six signal lines SGL(1), SGL(2), . . . , SGL(6) are coupled to a common output signal line Lout1. Six signal lines SGL(7), SGL(8), . . . , SGL(12) are coupled to a common output signal line Lout2. The output signal lines Lout1 and Lout2 are each coupled to the detection circuit 48.

The signal lines SGL(1), SGL(2), . . . , SGL(6) are grouped into a first signal line block, and the signal lines SGL(7), SGL(8), . . . , SGL(12) are grouped into a second signal line block. The selection signal lines Lsel are coupled to the gates of the respective third switching elements TrS included in one of the signal line blocks. One of the selection signal lines Lsel is coupled to the gates of the third switching elements TrS in the signal line blocks.

The control circuit 122 (refer to FIG. 1) sequentially supplies the selection signal ASW to the selection signal lines Lsel. This operation causes the signal line selection circuit 16 to operate the third switching elements TrS to sequentially select the signal lines SGL in one of the signal line blocks in a time-division manner. The signal line selection circuit 16 selects one of the signal lines SGL in each of the signal line blocks. With the above-described configuration, the detection device 1 can reduce the number of integrated circuits (ICs) including the detection circuit 48 or the number of terminals of the ICs. The signal line selection circuit 16 may couple more than one of the signal lines SGL collectively to the detection circuit 48.

As illustrated in FIG. 3, the reset circuit 17 includes a reference signal line Lvr, a reset signal line Lrst, and fourth switching elements TrR. The fourth switching elements TrR are provided correspondingly to the signal lines SGL. The reference signal line Lvr is coupled to either the sources or the drains of the fourth switching elements TrR. The reset signal line Lrst is coupled to the gates of the fourth switching elements TrR.

The control circuit 122 supplies a reset signal RST2 to the reset signal line Lrst. This operation turns on the fourth switching elements TrR to electrically couple the signal lines SGL to the reference signal line Lvr. The power supply circuit 123 supplies a reference signal COM to the reference signal line Lvr. This operation supplies the reference signal COM to a capacitive element Ca (refer to FIG. 4) included in each of the partial detection areas PAA.

FIG. 4 is a circuit diagram illustrating the partial detection areas. FIG. 4 also illustrates a circuit configuration of the detection circuit 48. As illustrated in FIG. 4, each of the partial detection areas PAA includes the photodiode PD, the capacitive element Ca, and a corresponding one of the first switching elements Tr. The capacitive element Ca is a capacitor (sensor capacitance) generated in the photodiode PD, and is equivalently coupled in parallel with the photodiode PD.

FIG. 4 illustrates two gate lines GCL(m) and GCL(m+1) arranged in the second direction Dy among the gate lines GCL. FIG. 4 also illustrates two signal lines SGL(n) and SGL(n+1) arranged in the first direction Dx among the signal lines SGL. The partial detection area PAA is an area surrounded by the gate lines GCL and the signal lines SGL.

The first switching elements Tr are provided corresponding to the photodiodes PD. Each of the first switching elements Tr includes a thin-film transistor, and in this example, includes an n-channel metal oxide semiconductor (MOS) thin-film transistor (TFT).

The gates of the first switching elements Tr belonging to the partial detection areas PAA arranged in the first direction Dx are coupled to the gate line GCL. The sources of the first switching elements Tr belonging to the partial detection areas PAA arranged in the second direction Dy are coupled to the signal line SGL. The drain of the first switching element Tr is coupled to the anode of the photodiode PD and the capacitive element Ca.

The cathode of the photodiode PD is supplied with the sensor power supply signal VDDSNS from the power supply circuit 123. The signal line SGL and the capacitive element Ca are supplied with the reference signal COM that serves as an initial potential of the signal line SGL and the capacitive element Ca from the power supply circuit 123.

When the partial detection area PAA is irradiated with light, a current corresponding to the amount of the light flows through the photodiode PD. As a result, an electric charge is stored in the capacitive element Ca. After the first switching element Tr is turned on, a current corresponding to the electric charge stored in the capacitive element Ca flows through the signal line SGL. The signal line SGL is coupled to the detection circuit 48 through a corresponding one of the third switching elements TrS of the signal line selection circuit 16. Thus, the detection device 1 can detect a signal corresponding to the amount of the light irradiating the photodiode PD in each of the partial detection areas PAA or each block unit PAG.

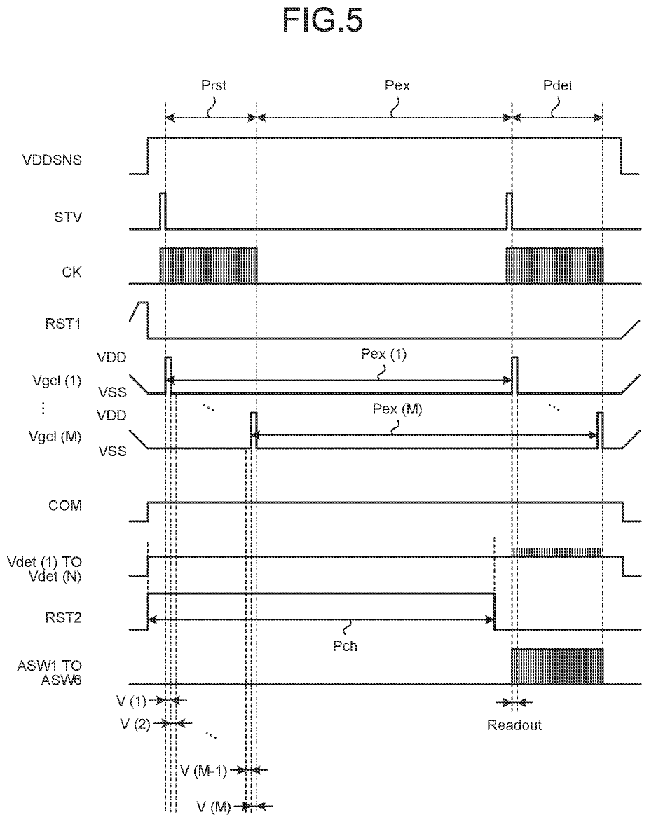

During a reading period Pdet (refer to FIG. 5), a switch SSW of the detection circuit 48 is turned on, and the detection circuit 48 is coupled to the signal lines SGL. The detection signal amplifier 42 of the detection circuit 48 converts a current supplied from the signal line SGL into a voltage corresponding to the value of the current, and amplifies the result. A reference potential (Vref) having a fixed potential is supplied to a non-inverting input terminal (+) of the detection signal amplifier 42, and the signal lines SGL are coupled to an inverting input terminal (−) of the detection signal amplifier 42. In the present embodiment, the same signal as the reference signal COM is supplied as the reference potential (Vref) voltage. The signal processor 44 (refer to FIG. 2) calculates the difference between the detection signal Vdet when the photodiode PD is irradiated by light and the detection signal Vdet when the photodiode PD is not irradiated by light, as each of the sensor output voltages Vo. The detection signal amplifier 42 includes a capacitive element Cb and a reset switch RSW. During a reset period Prst (refer to FIG. 5), the reset switch RSW is turned on, and an electric charge of the capacitive element Cb is reset.

The following describes an operation example of the detection device 1. FIG. 5 is a timing waveform diagram illustrating the operation example of the detection device. As illustrated in FIG. 5, the detection device 1 has the reset period Prst, an exposure period Pex, and the reading period Pdet. The power supply circuit 123 supplies the sensor power supply signal VDDSNS to the cathode of the optical sensor PD over the reset period Prst, the exposure period Pex, and the reading period Pdet. The sensor power supply signal VDDSNS is a signal that applies a reverse bias between the anode and the cathode of the photodiode PD. For example, the sensor power supply signal VDDSNS of substantially 2.75 V is applied to the cathode of the photodiode PD, and the reference signal COM of substantially 0.75 V is applied to the anode of the photodiode PD. As a result, a reverse bias of substantially 2.0 V is applied between the anode and the cathode. The reverse bias voltage may be set in the range of 1.5 V to 2.5 V. The control circuit 122 sets the reset signal RST2 to “H”, and then, supplies the start signal STV and the clock signal CK to the gate line drive circuit 15 to start the reset period Prst. During the reset period Prst, the control circuit 122 supplies the reference signal COM to the reset circuit 17, and uses the reset signal RST2 to turn on the fourth switching elements TrR for supplying a reset voltage. This operation supplies the reference signal COM as the reset voltage to each of the signal lines SGL. The reference signal COM is set to, for example, 0.75 V.

During the reset period Prst, the gate line drive circuit 15 sequentially selects each of the gate lines GCL based on the start signal STV, the clock signal CK, and the reset signal RST1. The gate line drive circuit 15 sequentially supplies the gate drive signals Vgcl {Vgcl(1), . . . , Vgcl(M)} to the gate lines GCL. The gate drive signal Vgcl has a pulsed waveform having a power supply voltage VDD serving as a high-level voltage and a power supply voltage VSS serving as a low-level voltage. In FIG. 5, M gate lines GCL (where M is, for example, 256) are provided, and the gate drive signals Vgcl(1), . . . , Vgcl(M) are sequentially supplied to the respective gate lines GCL. Thus, the first switching elements Tr are sequentially brought into a conducting state and supplied with the reset voltage on a row-by-row basis. For example, a voltage of 0.75 V of the reference signal COM is supplied as the reset voltage.

Thus, during the reset period Prst, the capacitive elements Ca of all the partial detection areas PAA are sequentially electrically coupled to the signal lines SGL, and are supplied with the reference signal COM. As a result, the capacitance of the capacitive elements Ca is reset. The capacitance of the capacitive elements Ca of some of the partial detection areas PAA can be reset by partially selecting the gate lines and the signal lines SGL.

Examples of the exposure timing control method include a control method of exposure during non-selection of gate lines and a full-time control method of exposure. In the control method of exposure during non-selection of gate lines, the gate drive signals {Vgcl(1), . . . , Vgcl(M)} are sequentially supplied to all the gate lines GCL coupled to the photodiodes PD serving as the detection targets, and all the photodiodes PD serving as the detection targets are supplied with the reset voltage. Then, after all the gate lines GCL coupled to the photodiodes PD serving as the detection targets are set to a low voltage (the first switching elements Tr are turned off), the actual exposure starts and the actual exposure is performed during the exposure period Pex. After the actual exposure ends, the gate drive signals {Vgcl(1), . . . , Vgcl(M)} are sequentially supplied to the gate lines GCL coupled to the photodiodes PD serving as the detection targets as described above, and reading is performed during the reading period Pdet. In the full-time control method of exposure, control for performing the exposure can also be performed during the reset period Prst and the reading period Pdet (full-time exposure control). In this case, the exposure period Pex(1) starts after the gate drive signal Vgcl(1) is supplied to the gate line GCL during the reset period Prst. The term “exposure period Pex {(1), . . . , (M)}” refers to a period during which the capacitive elements Ca are charged from the photodiodes PD. The electric charge stored in the capacitive element Ca during the reset period Prst causes a reverse directional current (from cathode to anode) to flow through the photodiode PD due to light irradiation, and the potential difference in the capacitive element Ca decreases. The start timing and the end timing of the actual exposure periods Pex(1), . . . , Pex(M) are different among the partial detection areas PAA corresponding to the gate lines GCL. Each of the exposure periods Pex(1), . . . , Pex(M) starts when the gate drive signal Vgcl changes from the power supply voltage VDD serving as the high-level voltage to the power supply voltage VSS serving as the low-level voltage during the reset period Prst. Each of the exposure periods Pex(1), . . . , Pex(M) ends when the gate drive signal Vgcl changes from the power supply voltage VSS to the power supply voltage VDD during the reading period Pdet. The lengths of exposure time of the exposure periods Pex(1), . . . , Pex(M) are equal.

In the control method of exposure during non-selection of gate lines, a current corresponding to the light irradiating the photodiode PD flows the photodiode PD in each of the partial detection areas PAA during the exposure period Pex {(1) . . . (M)}. As a result, an electric charge is stored in each of the capacitive elements Ca.

At a time before the reading period Pdet starts, the control circuit 122 sets the reset signal RST2 to a low-level voltage. This operation stops operation of the reset circuit 17. The reset signal may be set to a high-level voltage only during the reset period Prst. During the reading period Pdet, the gate line drive circuit 15 sequentially supplies the gate drive signals Vgcl(1) . . . , Vgcl(M) to the gate lines GCL in the same manner as during the reset period Prst.

Specifically, the gate line drive circuit 15 supplies the gate drive signal Vgcl(1) at the high-level voltage (power supply voltage VDD) to the gate line GCL(1) during a period V(1). The control circuit 122 sequentially supplies selection signals ASW1, . . . , ASW6 to the signal line selection circuit 16 during a period in which the gate drive signal Vgcl(1) is at the high-level voltage (power supply voltage VDD). This operation sequentially or simultaneously couples the signal lines SGL of the partial detection areas PAA selected by the gate drive signal Vgcl(1) to the detection circuit 48. As a result, the detection signal Vdet for each of the partial detection areas PAA is supplied to the detection circuit 48.

In the same manner, the gate line drive circuit 15 supplies the gate drive signals Vgcl(2), . . . , Vgcl(M−1), Vgcl(M) at the high-level voltage to gate lines GCL(2), . . . , GCL(M−1), GCL(M) during periods V(2), . . . , V(M−1), V(M), respectively. That is, the gate line drive circuit 15 supplies the gate drive signal Vgcl to the gate line GCL during each of the periods V(1), V(2), . . . , V(M−1), V(M). The signal line selection circuit 16 sequentially selects each of the signal lines SGL based on the selection signal ASW in each period in which the gate drive signal Vgcl is set to the high-level voltage. The signal line selection circuit 16 sequentially couples each of the signal lines SGL to one detection circuit 48. Thus, the detection device 1 can output the detection signals Vdet of all the partial detection areas PAA to the detection circuit 48 during the reading period Pdet.

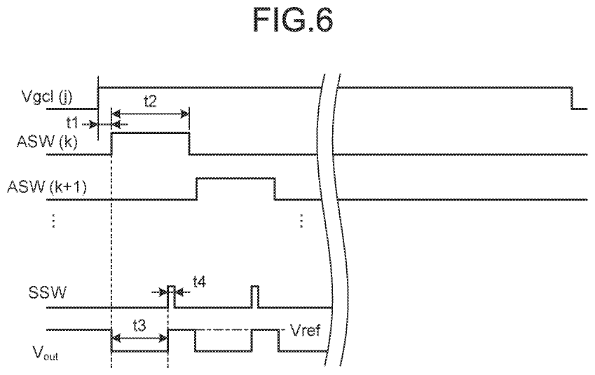

FIG. 6 is a timing waveform diagram illustrating an operation example during the reading period in FIG. 5. With reference to FIG. 6, the following describes the operation example during a supply period Readout of one gate drive signal Vgcl(j) in FIG. 5. In FIG. 5, the reference sign of the supply period “Readout” is assigned to the first gate drive signal Vgcl(1), and the same applies to the other gate drive signals Vgcl(2) . . . , Vgcl(M). The index j is any one of the natural numbers 1 to M.

As illustrated in FIGS. 6 and 4, the output voltage (Vₒᵤₜ) of each of the third switching elements TrS has been reset to the reference potential (Vref) voltage in advance. The reference potential (Vref) voltage serves as the reset voltage, and is set to, for example, 0.75 V. Then, the gate drive signal Vgcl(j) is set to a high level, and the first switching elements Tr of a corresponding row are turned on. Thus, each of the signal lines SGL in each row is set to a voltage corresponding to the electric charge stored in the capacitor (capacitive element Ca) of the partial detection area PAA. After a period t1 elapses from a rising edge of the gate drive signal Vgcl(j), a period t2 starts in which the selection signal ASW(k) is set to a high level. After the selection signal ASW(k) is set to the high level and the third switching element TrS is turned on, the electric charge stored in the capacitor (capacitive element Ca) of the partial detection area PAA coupled to the detection circuit 48 through the third switching element TrS changes the output voltage (Vₒᵤₜ) of the third switching element TrS (refer to FIG. 4) to a voltage corresponding to the electric charge stored in the capacitor (capacitive element Ca) of the partial detection area PAA (period t3). In the example of FIG. 6, this voltage is reduced from the reset voltage as illustrated in the period t3. Then, after the switch SSW is turned on (period t4 during which an SSW signal is set to a high level), the electric charge stored in the capacitor (capacitive element Ca) of the partial detection area PAA moves to the capacitor (capacitive element Cb) of the detection signal amplifier 42 of the detection circuit 48, and the output voltage of the detection signal amplifier 42 is set to a voltage corresponding to the electric charge stored in the capacitive element Cb. At this time, the potential of the inverting input portion of the detection signal amplifier 42 is set to an imaginary short-circuit potential of an operational amplifier, and therefore, set to the reference potential (Vref). The A/D converter 43 reads the output voltage of the detection signal amplifier 42. In the example of FIG. 6, waveforms of the selection signals ASW(k), ASW(k+1), . . . corresponding to the signal lines SGL of the respective columns are set to a high level to sequentially turn on the third switching elements TrS, and the same operation is sequentially performed. This operation sequentially reads the electric charges stored in the capacitors (capacitive elements Ca) of the partial detection areas PAA coupled to the gate line GCL. ASW(k), ASW(k+1), . . . in FIG. 6 are, for example, any of ASW1 to ASW6 in FIG. 3.

Specifically, after the period t4 starts in which the switch SSW is on, the electric charge moves from the capacitor (capacitive element Ca) of the partial detection area PAA to the capacitor (capacitive element Cb) of the detection signal amplifier 42 of the detection circuit 48. At this time, the non-inverting input (+) of the detection signal amplifier 42 is set to the reference potential (Vref) voltage (for example, 0.75 V). As a result, the output voltage (Vₒᵤₜ) of the third switching element TrS is also set to the reference potential (Vref) voltage due to the imaginary short-circuit between input ends of the detection signal amplifier 42. The voltage of the capacitive element Cb is set to a voltage corresponding to the electric charge stored in the capacitor (capacitive element Ca) of the partial detection area PAA at a location where the third switching element TrS is turned on in response to the selection signal ASW(k). After the output voltage (Vₒᵤₜ) of the third switching element TrS is set to the reference potential (Vref) voltage due to the imaginary short-circuit, the output voltage of the detection signal amplifier 42 reaches a voltage corresponding to the capacitance of the capacitive element Cb, and this output voltage is read by the A/D converter 43. The voltage of the capacitive element Cb is, for example, a voltage between two electrodes provided on a capacitor constituting the capacitive element Cb.

The period t1 is, for example, 20 μs. The period t2 is, for example, 60 μs. The period t3 is, for example, 44.7 μs. The period t4 is, for example, 0.98 μs.

Although FIGS. 5 and 6 illustrate the example in which the gate line drive circuit 15 selects the gate line GCL individually, the present disclosure is not limited to this example. The gate line drive circuit 15 may simultaneously select a predetermined number (two or more) of the gate lines GCL and sequentially supply the gate drive signals Vgcl to the gate lines GCL in units of the predetermined number of the gate lines GCL. The signal line selection circuit 16 may also simultaneously couple a predetermined number (two or more) of the signal lines SGL to one detection circuit 48. Moreover, the gate line drive circuit 15 may skip some of the gate lines GCL and scan the remaining ones.

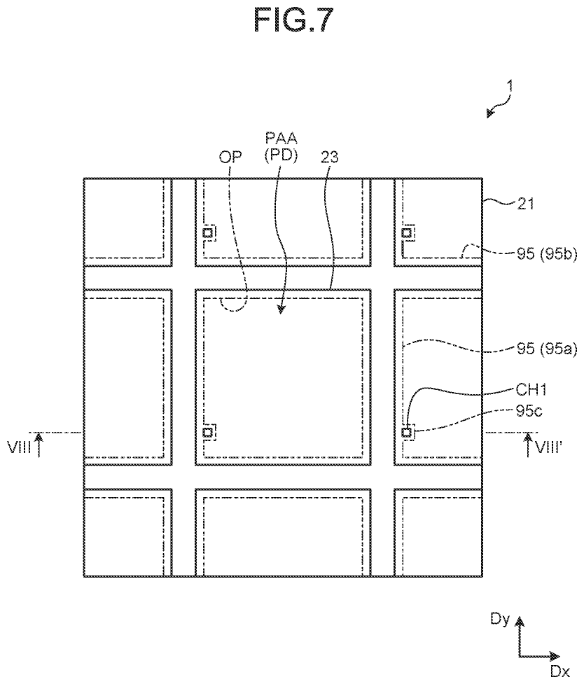

The following describes a configuration of the photodiode PD. FIG. 7 is a magnified schematic configuration diagram of the sensor. For ease of viewing, FIG. 7 illustrates an insulating film 95 with long dashed double-short dashed lines.

As illustrated in FIG. 7, the detection device 1 includes the photodiodes PD, a plurality of first electrodes 23, and the insulating film 95 that are provided on the sensor base member 21. The first electrodes 23 are provided in a matrix having a row-column configuration on the sensor base member 21 so as to correspond to the photodiodes PD. The first electrodes 23 are anode electrodes of the photodiodes PD and may be referred to as detection electrodes.

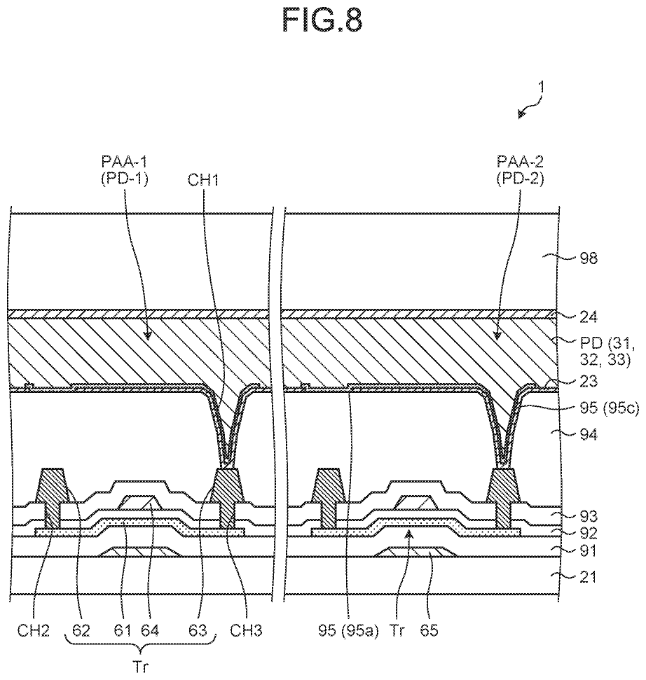

Each of the first electrodes 23 is electrically coupled to the first switching element Tr provided on the sensor base member 21 through a first contact hole CH1 formed in an organic insulating film 94 (refer to FIG. 8).

The insulating film 95 is provided between the first electrodes 23 adjacent in the first direction Dx and the second direction Dy and is provided so as to cover peripheries of the first electrodes 23. In more detail, the insulating film 95 is formed in a grid pattern in which first insulating films 95a intersect second insulating films 95b. The first insulating films 95a extend in the second direction Dy. The first insulating films 95a are provided so as to overlap sides of the first electrodes 23 extending in the second direction Dy. The second insulating films 95b extend in the first direction Dx. The second insulating films 95b are provided so as to overlap sides of the first electrodes 23 extending in the first direction Dx.

In other words, an opening OP is formed in the insulating film 95 in each of areas overlapping the first electrodes 23. The opening OP is an area surrounded by two of the first insulating films 95a and two of the second insulating films 95b. A third insulating film 95c is coupled to a side of the first insulating film 95a and is formed so as to cover the first contact hole CH1.

For example, the shapes and the arrangement pitches of the first electrodes 23 and the insulating film 95 illustrated in FIG. 7 are only exemplary and can be changed as appropriate according to the characteristics and the detection accuracy required for the detection device 1.

FIG. 8 is a VIII-VIII′ sectional view of FIG. 7. As illustrated in FIG. 8, the detection device 1 includes the sensor base member 21, the first switching elements Tr, the organic insulating film 94, the first electrodes 23, the insulating film 95, the photodiodes PD (only simply illustrated in FIG. 8), a second electrode 24, and a sealing film 98.

In this specification, a direction from the sensor base member 21 toward the photodiode PD in a direction orthogonal to a surface of the sensor base member 21 is referred to as “upper side” or simply “above/on”. A direction from the photodiode PD toward the sensor base member 21 is referred to as “lower side” or simply “below”.

The sensor base member 21 is an insulating base member, and is made using, for example, glass or a resin material. The sensor base member 21 is not limited to having a flat plate shape, and may have a curved surface. In this case, the sensor base member 21 can be a film-like resin.

The sensor base member 21 is provided with TFTs, such as the first switching elements Tr, and various types of wiring such as the gate lines GCL and the signal lines SGL. The sensor base member 21 with the TFTs and the various types of wiring formed thereon is a drive circuit board for driving the sensor for each predetermined detection area and is also called a backplane or an array substrate.

A light-blocking film 65 is provided on the sensor base member 21. The light-blocking film 65 is provided between a semiconductor layer 61 and the sensor base member 21. The light-blocking film 65 can restrain light from entering a channel region of the semiconductor layer 61 from the sensor base member 21 side.

An undercoat film 91 is provided above the sensor base member 21 so as to cover the light-blocking film 65. The undercoat film 91 is formed of, for example, an inorganic insulating film such as a silicon nitride film or a silicon oxide film. The undercoat film 91 is not limited to being configured as a single-layer film, and may be configured as multiple layers of inorganic insulating films.

The first switching element Tr (transistor) is provided on the sensor base member 21. The first switching element Tr includes the semiconductor layer 61, a source electrode 62, a drain electrode 63, and a gate electrode 64. The semiconductor layer 61 is provided above the undercoat film 91. For example, polysilicon is used as the semiconductor layer 61. The semiconductor layer 61 is, however, not limited thereto, and may be formed of, for example, a microcrystalline oxide semiconductor, an amorphous oxide semiconductor, or low-temperature polysilicon.

A gate insulating film 92 is provided on the undercoat film 91 so as to cover the semiconductor layer 61. The gate insulating film 92 is, for example, an inorganic insulating film such as a silicon oxide film. The gate electrode 64 is provided on the gate insulating film 92. In the example illustrated in FIG. 8, the first switching element Tr has a top-gate structure. However, the first switching element Tr is not limited thereto, and may have a bottom-gate structure, or a dual-gate structure in which the gate electrodes 64 are provided on both the upper side and the lower side of the semiconductor layer 61.

An interlayer insulating film 93 is provided on the gate insulating film 92 so as to cover the gate electrode 64. The interlayer insulating film 93 has, for example, a multilayered structure of a silicon nitride film and a silicon oxide film. The source electrode 62 and the drain electrode 63 are provided on the interlayer insulating film 93. The source electrode 62 is coupled to a source region of the semiconductor layer 61 through a second contact hole CH2 provided in the gate insulating film 92 and the interlayer insulating film 93. The drain electrode 63 is coupled to a drain region of the semiconductor layer 61 through a third contact hole CH3 provided in the gate insulating film 92 and the interlayer insulating film 93.

The organic insulating film 94 is provided on the interlayer insulating film 93 so as to cover the source electrode 62 and the drain electrode 63 of the first switching element Tr. The organic insulating film 94 is an organic planarizing film, and has a better coverage property for steps formed by wiring and provides better surface flatness than inorganic insulating materials formed by, for example, chemical vapor deposition (CVD).

The first electrode 23 and the insulating film 95 are provided on the organic insulating film 94. The photodiode PD is provided on the first electrode 23. In more detail, the first electrode 23 is provided on the organic insulating film 94 and is coupled to the drain electrode 63 of the first switching element Tr on the bottom surface of the first contact hole CH1 formed in the organic insulating film 94. The first electrode 23 is the anode electrode of the photodiode PD and is formed of, for example, a light-transmitting conductive material such as indium tin oxide (ITO).

Alternatively, when the detection device 1 is formed as, for example, a top-surface light receiving optical sensor, the first electrode 23 can be made using, for example, a metal material such as silver (Ag). Alternatively, the first electrode 23 may be a metal material such as aluminum (Al) or an alloy material containing at least one or more of these metal materials. As described above, the first electrodes 23 are disposed so as to be separated for each of the partial detection areas PAA (photodiodes PD).

The insulating film 95 is provided so as to partially cover the first electrode 23. In the present embodiment, the insulating film 95 is formed of an inorganic insulating film. The first insulating films 95a of the insulating film 95 are provided on the organic insulating film 94 between the adjacent first electrodes 23, and cover the peripheries of the first electrodes 23. Each of the first insulating films 95a is provided so as to overlap the source electrode 62 (signal line SGL). The insulating film 95 insulates the first electrodes 23 of the photodiodes PD adjacent to each other.

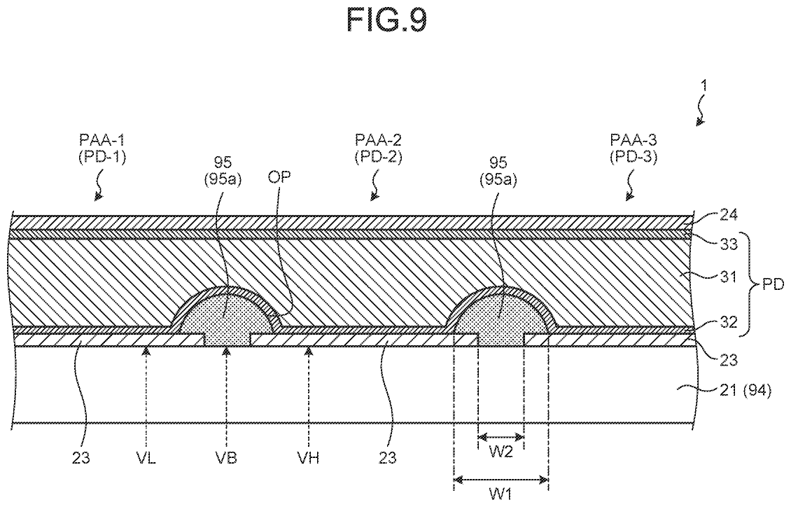

The third insulating film 95c is provided so as to cover the first electrode 23 in the first contact hole CH1 and overlaps the drain electrode 63. Since the third insulating film 95c is provided, a short circuit can be restrained from occurring between an active layer 31 and the first electrode 23 even if step disconnection of a hole transport layer 32 (refer to FIG. 9) occurs in the first contact hole CH1. The third insulating film 95c is not limited to the configuration of being coupled to the first insulating film 95a and may be provided in the first contact hole CH1 so as to be separated from the first insulating film 95a.

The photodiode PD has a larger area than that of the first electrode 23 in a plan view. The second electrode 24 is continuously provided across the partial detection areas PAA (photodiodes PD). More specifically, in FIG. 8, two of the partial detection areas PAA adjacent to each other are represented as a first partial detection area PAA-1 (first photodiode PD-1) and a second partial detection area PAA-2 (second photodiode PD-2). The first electrode 23 is provided in each of the first photodiode PD-1 and the second photodiode PD-2. The first photodiode PD-1 and the second photodiode PD-2 are formed of an organic semiconductor material that is shared by these photodiodes, and the organic semiconductor material is formed across the first electrodes 23.

The second electrode 24 is provided on the photodiodes PD. The second electrode 24 is the cathode electrodes of the photodiodes PD and is continuously formed over the partial detection areas PAA (photodiodes PD). More specifically, the second electrode 24 is continuously provided on the first and the second photodiodes PD-1 and PD-2. The second electrode 24 faces the first electrode 23 with the photodiode PD (active layer 31) interposed therebetween. The second electrode 24 is formed of, for example, a light-transmitting conductive material such as ITO or indium zinc oxide (IZO).

The sealing film 98 is provided on the second electrode 24. An inorganic film such as a silicon nitride film or an aluminum oxide film or a resin film such as an acrylic film is used as the sealing film 98. The sealing film 98 is not limited to a single layer and may be a multilayered film of two or more layers obtained by combining the inorganic film with the resin film described above. The sealing film 98 well seals the photodiode PD, and thus can restrain water from entering the photodiode PD from the upper surface side.

The following describes a detailed multilayered configuration of the first electrode 23, the insulating film 95, the photodiode PD, and the second electrode 24. FIG. 9 is a magnified schematic sectional view illustrating a magnified view of the multilayered structure of the first electrodes, the insulating film, the photodiodes, and the second electrode in FIG. 8. FIG. 9 does not illustrate the various switching elements and the various types of wiring formed on the sensor base member 21.

As illustrated in FIG. 9, the photodiode PD includes the active layer 31, the hole transport layer 32 (first carrier transport layer) provided between the active layer 31 and the first electrode 23, and an electron transport layer 33 (second carrier transport layer) provided between the active layer 31 and the second electrode 24. In other words, the hole transport layer 32, the active layer 31, and the electron transport layer 33 of the photodiode PD are stacked in this order in the direction orthogonal to the sensor base member 21.

The active layer 31 changes in characteristics (for example, voltage-current characteristics and a resistance value) depending on light emitted thereto. An organic material is used as a material of the active layer 31. Specifically, the active layer 31 has a bulk heterostructure in which a p-type organic semiconductor is mixed with an n-type fullerene derivative (PCBM) serving as an n-type organic semiconductor. As the active layer 31, low-molecular-weight organic materials can be used including, for example, fullerene (C₆₀), phenyl-C₆₁-butyric acid methyl ester (PCBM), copper phthalocyanine (CuPc), fluorinated copper phthalocyanine (F₁₆CuPc), 5,6,11,12-tetraphenyltetracene (rubrene), and perylene diimide (PDI) (derivative of perylene).

The active layer 31 can be formed by a vapor deposition process (dry process) using the above-listed low-molecular-weight organic materials. In this case, the active layer 31 may be, for example, a multilayered film of CuPc and F₁₆CuPc, or a multilayered film of rubrene and C₆₀. The active layer 31 can also be formed by a coating process (wet process). In this case, the active layer 31 is made using a material obtained by combining the above-listed low-molecular-weight organic materials with high-molecular-weight organic materials. As the high-molecular-weight organic materials, for example, poly(3-hexylthiophene) (P3HT) and F8-alt-benzothiadiazole (F8BT) can be used. The active layer 31 can be a film in the state of a mixture of P3HT and PCBM or a film in the state of a mixture of F8BT and PDI.

The hole transport layer 32 and the electron transport layer 33 are provided to facilitate holes and electrons generated in the active layer 31 to reach the first electrode 23 or the second electrode 24. The hole transport layer 32 directly contacts the top of the first electrode 23 through the opening OP of the insulating film 95. The active layer 31 directly contacts the top of the hole transport layer 32. The hole transport layer 32 is a metal oxide layer. For example, tungsten oxide (WO₃) or molybdenum oxide is used as the oxide metal layer.

The electron transport layer 33 directly contacts the top of the active layer 31, and the second electrode 24 directly contacts the top of the electron transport layer 33. Ethoxylated polyethylenimine (PEIE) is used as a material of the electron transport layer 33.

The materials and the manufacturing methods of the hole transport layer 32, the active layer 31, and the electron transport layer 33 are merely examples, and other materials and manufacturing methods may be used.

As described above, the insulating film 95 is provided between the adjacent first electrodes 23. A width W1 of the insulating film 95 is greater than a gap W2 between the adjacent first electrodes 23. In FIG. 9, the insulating film 95 is an organic insulating film formed of an organic material (for example, a hard coat film), and the height (thickness) of the insulating film 95 is greater than the height (thickness) of the first electrode 23.

The hole transport layer 32, the active layer 31, and the electron transport layer 33 forming the photodiodes PD are provided so as to cover the first electrodes 23 and the insulating film 95 between the adjacent first electrodes 23. In more detail, the hole transport layer 32, the active layer 31, and the electron transport layer 33 are continuously provided over the first partial detection area PAA-1 (first photodiode PD-1), the second partial detection area PAA-2 (second photodiode PD-2), and a third partial detection area PAA-3 (third photodiode PD-3). The hole transport layer 32 is formed along asperities formed by the first electrodes 23 and the insulating film 95. The active layer 31 is formed to have a thickness in an area overlapping the insulating film 95 less than that in an area overlapping the first electrode 23.

The detection device 1 is stacked in the order of the first electrode 23, the hole transport layer 32, the active layer 31, the electron transport layer 33, and the second electrode 24 in the area overlapping the first electrode 23. In an area not overlapping the first electrode 23, the insulating film 95, the hole transport layer 32, the active layer 31, the electron transport layer 33, and the second electrode 24 are stacked in this order.

The following describes a case where one of the first electrodes 23 (first photodiode PD-1) adjacent to the insulating film 95 is supplied with a first potential VL, and the other of the first electrodes 23 (second photodiode PD-2) adjacent to the insulating film 95 is supplied with a second potential VH. The first potential VL is lower than the second potential VH.

In the present embodiment, due to the configuration provided with the insulating film 95, the distance between the hole transport layer 32 and the electron transport layer 33 (second electrode 24) in the area overlapping the insulating film 95 is shorter than the distance between the hole transport layer 32 and the electron transport layer 33 (second electrode 24) in the area overlapping the first electrode 23. Therefore, a third potential VB of the hole transport layer 32 in the area overlapping the insulating film 95 is higher than the first potential VL of the hole transport layer 32 in an area overlapping the one of the first electrodes 23 (first photodiode PD-1) adjacent to the insulating film 95. In addition, the third potential VB of the hole transport layer 32 in the area overlapping the insulating film 95 is higher than the second potential VH of the hole transport layer 32 in an area overlapping the other of the first electrodes 23 (second photodiode PD-2) adjacent to the insulating film 95. For example, the potential of the hole transport layer 32 increases in the order of the first potential VL, the second potential VH, and the third potential VB.

With this configuration, even when one of the first photodiode PD-1 and the second photodiode PD-2 is irradiated with light to generate a potential difference between the adjacent first electrodes 23 (for example, in the case where the second potential VH of the second photodiode PD-2 is higher than the first potential VL of the first photodiode PD-1), the third potential VB of the hole transport layer 32 in the area overlapping the insulating film 95 is higher than the first potential VL and the second potential VH. As a result, the hole transport layer 32 in the area overlapping the insulating film 95 serves as a potential barrier, and thus, a leakage current can be restrained from flowing between the adjacent first electrodes 23.

Since the insulating film 95 forms the potential barrier between the first electrodes 23, the gap W2 between the first electrodes 23 can be made smaller than that without the insulating film 95, which allows the detection device 1 to have higher resolution. The insulating film 95 is provided so as to cover the peripheries of the first electrodes 23. That is, the insulating film 95 is provided so as to cover steps formed by the organic insulating film 94 and the first electrodes 23. This configuration can restrain the step disconnection of the hole transport layer 32 as compared with the case where the insulating film 95 is not provided and the hole transport layer 32 is formed along the steps formed by the organic insulating film 94 and the first electrodes 23.

The width W1 and the height of the insulating film 95 illustrated in FIG. 9 are exaggerated for facilitating the explanation. The width W1 and the height of the insulating film 95 can be changed as appropriate. For example, in FIG. 9, the sectional shape of the insulating film 95 is illustrated in a semicircular shape, but this is only schematically illustrated. The upper surface of the insulating film 95 may be formed to be flat. While FIG. 9 illustrates the first electrodes 23 adjacent in the first direction Dx and the first insulating films 95a each provided between the first electrodes 23 adjacent in the first direction Dx, the description about FIG. 9 can also be applicable to the first electrodes 23 adjacent in the second direction Dy and the second insulating films 95b each provided between the first electrodes 23 adjacent in the second direction Dy. That is, the insulating film 95 is provided around one first electrode 23, and the potential barrier is formed around one first electrode 23.

### Second Embodiment

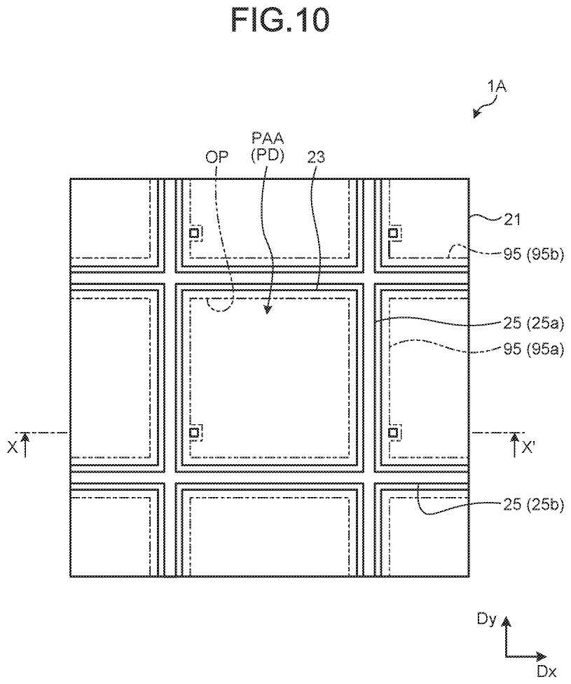

FIG. 10 is a magnified schematic configuration diagram of the sensor of a detection device according to a second embodiment. In the following description, the same components as those described in the embodiment above are denoted by the same reference numerals, and the description thereof will not be repeated.

As illustrated in FIG. 10, a detection device 1A according to the second embodiment further includes shield wiring 25. The shield wiring 25 is provided between the adjacent first electrodes 23. The insulating film 95 is provided so as to cover the shield wiring 25. That is, the shield wiring 25 and the insulating film 95 are both provided in a grid pattern.

In more detail, the shield wiring 25 is formed in a grid pattern in which a plurality of first shield lines 25a intersect a plurality of second shield lines 25b. The first shield lines 25a extend in the second direction Dy. The second shield lines 25b extend in the first direction Dx. The first shield lines 25a and the second shield lines 25b are provided so as to be separate from the first electrodes 23. Each of the first electrodes 23 is disposed in an area defined by the shield wiring 25.

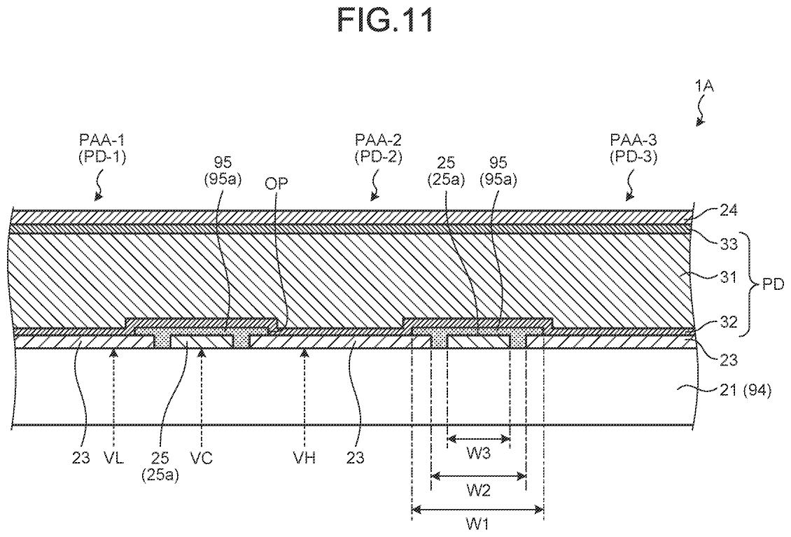

FIG. 11 is a magnified schematic sectional view illustrating a magnified view of a multilayered structure of the first electrodes, the shield wiring, the insulating film, the photodiodes, and the second electrode of the detection device according to the second embodiment. FIG. 11 is a X-X′ sectional view of FIG. 10. As illustrated in FIG. 11, the shield wiring 25 is provided in the same layer as that of the first electrodes 23 on the organic insulating film 94. The shield wiring 25 is formed of the same material (such as ITO) as that of the first electrodes 23. Alternatively, the shield wiring 25 may be formed of a different material from that of the first electrodes 23.

The insulating film 95 is provided between the adjacent first electrodes 23 and covers the shield wiring 25 and the peripheries of the first electrodes 23. A width W3 of the shield wiring 25 is less than the gap W2 between the adjacent first electrodes 23. In addition, the width W1 of the insulating film 95 is greater than the gap W2 between the adjacent first electrodes 23 and the width W3 of the shield wiring 25. In the second embodiment, the insulating film 95 is an inorganic insulating film formed of an inorganic material (such as a silicon nitride film or a silicon oxide film). The insulating film 95, however, may be an organic insulating film in the same manner as in the first embodiment.

The hole transport layer 32, the active layer 31, and the electron transport layer 33 forming the photodiodes PD are provided so as to cover the first electrodes 23 as well as the insulating film 95 and the shield wiring 25 that are provided between the adjacent first electrodes 23. The hole transport layer 32, the active layer 31, and the electron transport layer 33 are stacked in this order on the shield wiring 25 with the insulating film 95 interposed therebetween.

The shield wiring 25 is supplied with a fixed potential VC. The fixed potential VC is higher than the first potential VL supplied to one of the first electrodes 23 (first photodiode PD-1) adjacent to the shield wiring 25. The fixed potential VC is also higher than the second potential VH supplied to the other of the first electrodes 23 (second photodiode PD-2) adjacent to the shield wiring 25. For example, the potential increases in the order of the first potential VL, the second potential VH, and the fixed potential VC. For example, a signal having the same potential as that of the sensor power supply signal VDDSNS supplied to the cathode of the photodiode PD is supplied as the fixed potential VC to the shield wiring 25. In this case, the fixed potential VC is substantially 2.75 V. That is, the fixed potential VC supplied to the shield wiring 25 is equal to or higher than the potential of the second electrode 24 (sensor power supply signal VDDSNS).

In the second embodiment, the potential of the hole transport layer 32 in an area overlapping the shield wiring 25 is higher than the first potential VL of the hole transport layer 32 in an area overlapping one of the first electrodes 23 (first photodiode PD-1) adjacent to the insulating film 95 and the shield wiring 25. The potential of the hole transport layer 32 in the area overlapping the shield wiring 25 is also higher than the second potential VH of the hole transport layer 32 in an area overlapping the other of the first electrodes 23 (second photodiode PD-2) adjacent to the insulating film 95 and the shield wiring 25. As a result, the hole transport layer 32 in the area overlapping the shield wiring 25 serves as the potential barrier, and thus, the leakage current can be restrained from flowing between the adjacent first electrodes 23.

The fixed potential VC supplied to the shield wiring 25 may be different from the sensor power supply signal VDDSNS.

### Modification of Second Embodiment

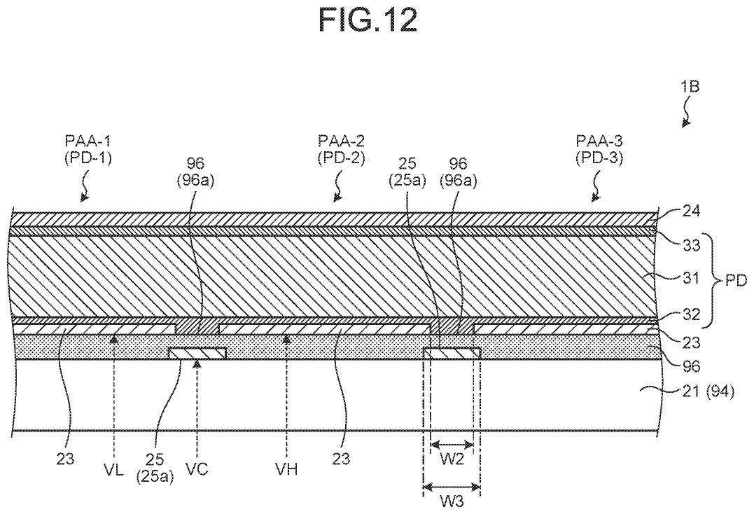

FIG. 12 is a magnified schematic sectional view illustrating a magnified view of a multilayered structure of the first electrodes, the shield wiring, the insulating film, the photodiodes, and the second electrode of a detection device according to a modification of the second embodiment. As illustrated in FIG. 12, in a detection device 1B according to the modification of the second embodiment, the shield wiring 25 is provided in a different layer from that of the first electrodes 23. The shield wiring 25 is provided in a layer closer to the sensor base member 21 than the first electrodes 23, that is, between the sensor base member 21 and the layer in which the first electrodes 23 are formed.

In more detail, the shield wiring 25 is provided on the organic insulating film 94. An insulating film 96 is provided on the organic insulating film 94 so as to cover the shield wiring 25. The first electrodes 23 are provided on the insulating film 96.

The hole transport layer 32, the active layer 31, and the electron transport layer 33 forming the photodiodes PD are provided on the insulating film 96 so as to cover the first electrodes 23. In other words, the hole transport layer 32, the active layer 31, and the electron transport layer 33 are provided so as to cover the first electrodes 23 and insulating films 96a between the adjacent first electrodes 23.

In the present modification, the width W3 of the shield wiring 25 is greater than the gap W2 between the adjacent first electrodes 23. That is, since the shield wiring 25 is provided in a different layer from that of the first electrodes 23, restrictions on the arrangement of the first electrodes 23 are less severe than those in the second embodiment described above, which allows the gap W2 between the first electrodes 23 to be reduced. As a result, the detection device 1B according to the modification of the second embodiment can achieve a higher resolution of detection.

Also, in the present modification, the width W3 of the shield wiring 25 may be less than the gap W2 between the adjacent first electrodes 23.

While FIGS. 11 and 12 illustrate the first electrodes 23 adjacent in the first direction Dx and the first shield line 25a provided between the first electrodes 23 adjacent in the first direction Dx, the description about FIGS. 11 and 12 can also be applicable to the first electrodes 23 adjacent in the second direction Dy and the second shield lines 25b provided between the first electrodes 23 adjacent in the second direction Dy. That is, the shield wiring 25 is provided around one first electrode 23, and the potential barrier is formed around one first electrode 23.

In the first embodiment, the second embodiment, and the modification described above, the first electrode 23 is the anode electrode of the photodiode PD, and the second electrode 24 is the cathode electrode of the photodiode PD. However, the present disclosure is not limited thereto. The first electrode 23 may be the cathode electrode of the photodiode PD, and the second electrode 24 may be the anode electrode of the photodiode PD. In this case, the photodiode PD is configured so as to have layers that are stacked in the order of the electron transport layer 33 (first carrier transport layer), the active layer 31, and the hole transport layer 32 (second carrier transport layer) in the direction orthogonal to the sensor base member 21.

While the preferred embodiments of the present disclosure have been described above, the present disclosure is not limited to the embodiments described above. The content disclosed in the embodiments is merely an example, and can be variously modified within the scope not departing from the gist of the present disclosure. Any modifications appropriately made within the scope not departing from the gist of the present disclosure also naturally belong to the technical scope of the present disclosure. At least one of various omissions, substitutions, and changes of the components can be made without departing from the gist of the embodiments and the modification described above.

What is claimed is:

1. A detection device comprising:
a substrate;
a plurality of first electrodes arranged on the substrate;
an insulating film provided between the first electrodes adjacent to each other;
a plurality of photodiodes provided so as to correspond to the first electrodes; and
a second electrode provided across the photodiodes, wherein
the photodiodes each comprise a first carrier transport layer, an active layer, and a second carrier transport layer stacked on the substrate, and
the first carrier transport layer, the active layer, and the second carrier transport layer are provided so as to cover the first electrodes and the insulating film between the adjacent first electrodes.

2. The detection device according to claim 1, further comprising shield wiring that is provided between the adjacent first electrodes and is configured to be supplied with a fixed potential, wherein
the insulating film is provided so as to cover the shield wiring.

3. The detection device according to claim 2, wherein the shield wiring is provided in the same layer as a layer of the first electrodes.

4. The detection device according to claim 2, wherein the shield wiring is provided in a layer that is different from a layer of the first electrodes and that is located between the substrate and the layer of the first electrodes.

5. The detection device according to claim 2, wherein
the shield wiring is provided in a grid pattern, and
each of the first electrodes is disposed in an area defined by the shield wiring.

6. The detection device according to claim 2, wherein the fixed potential supplied to the shield wiring is higher than a potential of each of the first electrodes.

7. The detection device according to claim 2, wherein the fixed potential supplied to the shield wiring is equal to or higher than a potential of the second electrode.

8. The detection device according to claim 1, wherein the insulating film is an organic insulating film or an inorganic insulating film.

9. The detection device according to claim 1, wherein at least either one of each first electrode and the second electrode is made of a light-transmitting conductive material.

10. The detection device according to claim 1, wherein
the insulating film covers peripheries of the first electrodes and is provided with openings in areas overlapping the first electrodes, and
the first carrier transport layer is in contact with the first electrodes through the openings.

11. The detection device according to claim 1, wherein
the first electrodes, the first carrier transport layer, the active layer, the second carrier transport layer, and the second electrode are stacked in the order as listed, in areas overlapping the first electrodes,
the insulating film, the first carrier transport layer, the active layer, the second carrier transport layer, and the second electrode are stacked in the order as listed, in areas not overlapping the first electrodes, and
a height of the insulating film is greater than a height of the first electrodes.

12. The detection device according to claim 1, wherein
one of each first electrode and the second electrode is a cathode electrode, and
the other of each first electrode and the second electrode is an anode electrode.

13. The detection device according to claim 1, wherein
one of the first carrier transport layer and the second carrier transport layer is a hole transport layer, and
the other of the first carrier transport layer and the second carrier transport layer is an electron transport layer.
